(19) United States
(12) Patent Application Publication
(10) Pub. No.: US 2010/0244212 A1
(43) Pub. Date: Sep. 30, 2010

(54) INTEGRATED CIRCUIT PACKAGING SYSTEM WITH POST TYPE INTERCONNECTOR AND METHOD OF MANUFACTURE THEREOF

(76) Inventors: Jong-Woo Ha, Seoul (KR); DongSoo Moon, Ichon-si (KR); SooMoon Park, Jinju-si (KR)

Correspondence Address: LAW OFFICES OF MIKIO ISHIMARU, 333 W. EL CAMINO REAL, SUITE 330, SUNNYVALE, CA, 94087, US

(21) Appl. No.: 12/412,886

(22) Filed: Mar. 27, 2009

(51) Int. Cl. H01L 23/538; H01L 21/56

(52) U.S. Cl. 257/676; 438/127; 257/E21.502; 257/E23.169

(57) ABSTRACT

A method of manufacture of an integrated circuit packaging system includes: providing a bottom package including a first device over a first substrate and a second substrate over the first device; forming an encapsulation material over the bottom package with an opening over the second substrate; and forming a conductive post within the opening.

### CROSS-REFERENCE TO RELATED APPLICATION(S)

The present application contains subject matter related to co-pending U.S. patent application Ser. No. 11/934,069 filed Nov. 1, 2007. The related application is assigned to STATS ChipPAC LTD. and the subject matter thereof is incorporated herein by reference thereto.

### TECHNICAL FIELD

The present invention relates generally to an integrated circuit packaging system, and more particularly to a system for vertically integrated stacked electronic devices and/or packages employing post type interconnectors.

### BACKGROUND ART

Integrated circuits and integrated circuit packaging systems can be found in a multitude of portable electronic devices, such as smart phones, pocket PCs, digital cameras, location based devices, and other wireless products. Today's customers and electronics systems are demanding that these integrated circuit systems provide maximum functional integration of memory and logic within the smallest footprint, lowest profile, and lowest cost package available. Consequently, manufacturer's are turning to three-dimensional packaging to achieve the required high level of functional integration necessary to support these mobile multimedia products.

In response to these demands many innovative package designs have been conceived and brought to market. By way of example, the multi-chip module package has achieved a prominent role in reducing footprint, profile, and cost of modern electronics. However, these multi-chip modules, whether vertically or horizontally arranged, can also present problems because they usually must be assembled before the component chips and chip connections can be tested.

Exemplary multi-chip modules may include multiple die stacked in a package or multiple packages stacked in a package, such as package-on-package configurations (PoP). PoP configurations may include stacking of two or more packages, wherein known-good-die (KGD) and assembly process yields are not an issue because each package can be tested prior to assembly, thereby permitting KGD to be used in assembling the package stack. However, package level stacking can pose other problems.

One such problem is package-to-package assembly process difficulties caused by irregularities in the flatness/coplanarity of the lower package. Another problem results from poor heat dissipation from the upper package. Still another problem arises from electrical shorts between solder balls formed to close together to accommodate the increased need for more input/output (I/O) connections between the upper and lower packages. Yet another problem arises when the top surface of each I/O solder ball used to form interconnections between upper and lower packages becomes partially covered by mold flash, thereby reducing the reliability of the interconnection and the device.

Thus, a need still remains for a reliable integrated circuit packaging system, method of fabrication, and device design, wherein the integrated circuit packaging system increases the number of I/O counts between packages, while reducing the likelihood of reliability problems from mold flash and electrical shorts. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested

### DISCLOSURE OF THE INVENTION

The present invention provides a method of manufacture of an integrated circuit packaging system including: providing a bottom package including a first device over a first substrate and a second substrate over the first device; forming an encapsulation material over the bottom package with an opening over the second substrate; and forming a conductive post within the opening.

The present invention provides an integrated circuit packaging system, including: a bottom package including a first device over a first substrate and a second substrate over the first device; a leadframe interposer with a conductive post over the second substrate; and an encapsulation material.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a partial cross-sectional view of an integrated circuit packaging system, in a first embodiment of the present invention.

FIG. 2 is a partial cross-sectional view of a bottom package in a stage of manufacture, in accordance with an embodiment of the present invention.

FIG. 3 is the structure of FIG. 2 during deposition of an encapsulation material.

FIG. 4 is the structure of FIG. 3 after depositing an encapsulation material.

FIG. 5 is a partial cross-sectional view of the structure of FIG. 4 after forming a conductive post, in accordance with an embodiment of the present invention.

FIG. 6 is a partial cross-sectional view of the structure of FIG. 4 after forming a conductive post, in accordance with another embodiment of the present invention.

FIG. 7 is a partial cross-sectional view of the structure of FIG. 4 after forming a conductive post, in accordance with another embodiment of the present invention.

FIG. 8 is a partial cross-sectional view of a bottom package in an initial stage of manufacture, in accordance with another embodiment of the present invention.

FIG. 9 is the structure of FIG. 8 after joining a second substrate to a first device.

FIG. 10 is the structure of FIG. 9 after forming an encapsulation material.

FIG. 11 is a partial cross-sectional view of a bottom package, in accordance with another embodiment of the present invention.

FIG. 12 is a partial cross-sectional view of a bottom package, in accordance with another embodiment of the present invention.

FIG. 13 is a partial cross-sectional view of a bottom package, in accordance with another embodiment of the present invention.

FIG. 14 is a partial cross-sectional view of a bottom package, in accordance with another embodiment of the present invention.

FIG. 15 is a partial cross-sectional view of a bottom package, in accordance with another embodiment of the present invention.

FIG. 16 is a partial cross-sectional view of a bottom package, in accordance with another embodiment of the present invention.

FIG. 17 is a partial cross-sectional view of an integrated circuit packaging system in accordance with another embodiment of the present invention.

FIG. 18 is a partial cross-sectional view of a second substrate in an initial stage of manufacture, in accordance with another embodiment of the present invention.

FIG. 19 is a partial cross-sectional view of a bottom package including an interface during a stage of manufacture, in accordance with another embodiment of the present invention.

FIG. 20 is the structure of FIG. 19 after joining a second substrate to a first device via an interposer.

FIG. 21 is the structure of FIG. 20 after forming an encapsulation material.

FIG. 22 is a partial cross-sectional view of a second substrate in an initial stage of manufacture, in accordance with another embodiment of the present invention.

FIG. 23 is the structure of FIG. 22 after formation of a first conductive post.

FIG. 24 is the structure of FIG. 23 after formation of a second passivation layer.

FIG. 25 is the structure of FIG. 24 after formation of an interface 1700.

FIG. 26 is the structure of FIG. 25 after further processing.

FIG. 27 is a partial cross-sectional view of a bottom package including a first conductive post and an interface during a stage of manufacture, in accordance with another embodiment of the present invention.

FIG. 28 is the structure of FIG. 27 after joining a second substrate to a first device via an interposer.

FIG. 29 is the structure of FIG. 28 after forming an encapsulation material.

FIG. 30 is a flow chart of a method of manufacture of an integrated circuit packaging system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals.

For expository purposes, the term “horizontal” as used herein is defined as a plane parallel to the conventional plane or surface of the first substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact among elements and may or may not include an adhesive formed therebetween.

The term “processing” as used herein includes deposition of material or photoresist, patterning, exposure, development, etching, cleaning, and/or removal of the material or photoresist as required in forming a described structure.

The terms “example” or “exemplary” are used herein to mean serving as an instance or illustration. Any aspect or embodiment described herein as an “example” or as “exemplary” is not necessarily to be construed as preferred or advantageous over other aspects or designs.

The terms “first” and “second” as used herein are for purposes of differentiation between elements only and are not to be construed as limiting the scope of the present invention.

The term “conductive post” is defined as meaning an electrical interconnection not formed by solder balls between adjacent structures.

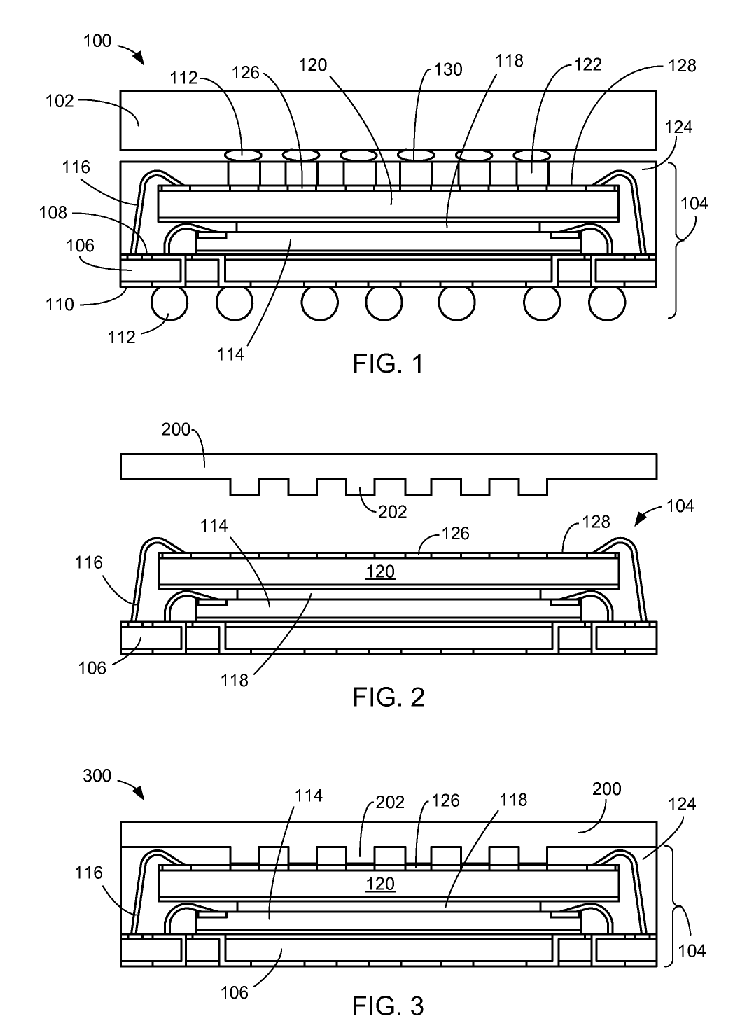

FIGS. 1-29, which follow, depict by way of example and not by limitation, exemplary embodiments for the formation of an integrated circuit packaging system and they are not to be construed as limiting. It is to be understood that a plurality of conventional processes that are well known within the art and not repeated herein, may precede or follow FIGS. 1-29. Moreover, it is to be understood that many modifications, additions, and/or omissions may be made to the below described processes and/or embodiments without departing from the scope of the claimed subject matter. For example, the below described processes and/or embodiments may include more, fewer, or other steps. Additionally, steps may be performed in any suitable order without departing from the scope of the present invention.

Moreover, it is to be appreciated that the integrated circuit packaging system of the present disclosure may include any number of stacked devices and/or packages, such as but not limited to, memory circuits, logic circuits, analog circuits, digital circuits, passive circuits, RF circuits, or a combination thereof, for example. Moreover, it is to be understood that the integrated circuit packaging system manufactured by the embodiments described herein can be used within processor components, memory components, logic components, digital components, analog components, mixed-signal components, power components, radio-frequency (RF) components, digital signal processor components, micro-electromechanical components, optical sensor components, or a combination thereof, in numerous configurations and arrangements as may be needed.

Furthermore, it is to be understood that one or more of the integrated circuit packaging system could be prepared at one time on a medium, which could be separated into individual or multiple integrated circuit package assemblies at a later stage of fabrication.

Referring now to FIG. 1, therein is shown a partial cross-sectional view of an integrated circuit packaging system 100, in a first embodiment of the present invention.

In at least one embodiment, the integrated circuit packaging system 100 can be a fan-in package-on-package (FiPOP) configuration, i.e., a three dimensional package that stacks a top package 102 over a bottom package 104, wherein each package may contain fully tested components. Generally, and by way of example, the bottom package 104 may include a fine ball grid array type package with one or more digital, analog, or hybrid circuits, wherein the mountable top surface of the bottom package 104 provides land pads that allow another package or component (i.e., the top package 102) to be stacked on top. Moreover, by way of example, the top package 102 may include one or more digital circuits, analog circuits, or memory stacks for a digital processor or system memory.

It will be appreciated by those skilled in the art that the versatile design afforded by FiPOP configurations accommodates multiple die and larger die sizes in a reduced footprint as compared to conventional package-on-package (PoP) solutions, while permitting flexibility to stack off the shelf memory packages with center ball grid array patterns on the top surface. Moreover, FiPOP still leverages the preferred business model of PoP in which logic device manufacturers provide the bottom package 104 and typically memory device manufacturers provide the top package 102, allowing the end user to configure as needed tested good packages.

In at least one embodiment, the bottom package 104 may include a first substrate 106 with a first surface 108 positioned parallel and opposing a second surface 110.

In such cases, the first substrate 106 may include a carrier substrate, a semiconductor substrate or a multi-layer structure (e.g., a laminate with one or more conductive layers separated by an insulator) suitable for electrically interconnecting integrated circuit systems formed on or above the first surface 108 of the first substrate 106 to external electrical circuits. In other embodiments, the first substrate 106 may include a thin metal sheet (e.g., a leadframe) or a conductive plated pattern on plastic tape suitable for electrically interconnecting integrated circuit systems formed on or above the first surface 108 of the first substrate 106 to external electrical circuits.

However, it is to be understood that the first substrate 106 is not to be limited to these examples. In accordance with the invention, the first substrate 106 may include any electrical interconnection structure that facilitates the incorporation of the integrated circuit packaging system 100 into a higher-level assembly, such as a printed circuit board or other suitable structure for supporting and/or electrically interfacing with the integrated circuit packaging system 100. As an exemplary illustration, the second surface 110 of the first substrate 106 may also be designed/engineered to electrically interface with another package structure, such as another one of the integrated circuit packaging system 100.

In at least one embodiment, the second surface 110 of the first substrate 106 may include an external terminal 112, such as a solder ball formed as part of a ball grid array structure. The external terminal 112 provides an electrical interface or interconnection between the integrated circuit packaging system 100 and external electrical circuits. More specifically, an electrical trace system within the first substrate 106 can receive an electrical signal from the external terminal 112 and transmit the electrical signal between the second surface 110 and the first surface 108 of the first substrate 106 or vice versa. Although the present embodiment depicts the external terminal 112 as a solder ball, it is to be understood that the external terminal 112 may include any interface connection technology, such as a pin or land grid array, that establishes electrical contact between the integrated circuit packaging system 100 and external electrical circuits.

Formed over or on the first surface 108 of the first substrate 106 is a first device 114. The first device 114 can be attached to the first substrate 106 by adhesives well known within the art and not described herein. In at least one embodiment, the first device 114 is attached to the first substrate 106 utilizing zero fillet technology.

Generally, the first device 114 may include one or more active devices, passive devices, or a combination thereof, vertically stacked or located within the same plane. By way of example, and not by way of limitation, the first device 114 may include one or more semiconductor chips or die that transmit, receive, modulate, and/or alter electrical signals, such as stacked devices, modular devices, ASIC devices, memory devices, RF devices, analog devices or a combination thereof. Furthermore, the first device 114 may further include, by way of example and not by way of limitation, one or more integrated circuit packages that transmit, receive, modulate and/or alter electrical signals, such as leaded and non-leaded packages, internal stacking module packages, flip-chip packages, modular packages, application-specific-integrated-circuit (ASIC) packages, RF packages, analog packages, memory packages, stacked die packages or a combination thereof. Additionally, the first device 114 may also include a pre-molded configuration.

However, it is to be understood that the first device 114 covers a wide range of semiconductor chip and integrated circuit package configurations involving various sizes, dimensions, and functional applications, and the type of chip or package configuration employed should only be limited by the design specifications of the integrated circuit package.

Moreover, it will be appreciated by those skilled in the art that the present embodiments permit the testing of the first device 114 before adhering it to the first substrate 106, thereby ensuring the use of known good die or packages in the manufacturing process. Additionally, after adhering the first device 114 to the first substrate 106, this assembly can also be tested before incorporation into additional package systems. This ensures that the final product includes known good assemblies, thereby improving the manufacturing process yield for the integrated circuit packaging system 100.

The first device 114 may be electrically connected to the first surface 108 of the first substrate 106 by an interconnection 116, such as a bond wire. The interconnection 116 can be deposited using materials and techniques well known within the art and is currently only limited by the technology of wire bond equipment and the minimum required operating space. Generally, the interconnection 116 can be located around one or more sides along the periphery of the first device 114, thereby permitting offset stacking, which may permit more products to meet the specified design requirements of the integrated circuit packaging system 100. However, in other embodiments, the first device 114 may be electrically connected to the first substrate 106 by flip-chip methods.

An interposer 118 can be mounted over or on the first device 114 and may include a die attach material with or without thermally conducting capabilities, a spacer, an electromagnetic interference shield for blocking potentially disruptive energy fields, or a combination thereof. Additionally, the interposer 118 can be strategically designed to help reduce the amount of warpage that the integrated circuit packaging system 100 may encounter during thermal cycling. It will be appreciated by those skilled in the art that the thickness of the interposer 118 may vary with the loop height of the interconnection 116. In at least one embodiment, the interposer 118 can be centrally located over the first device 114 and does not overlap and/or envelop the interconnection 116. In other embodiments, the interposer 118 can cover the first device 114 including the interconnection 116, thereby creating a lead-in-film structure.

A second substrate 120 can be formed over or on the interposer 118. In such cases, the second substrate 120 can be supported by the interposer 118. In at least one embodiment, the second substrate 120 may include a printed circuit board, a semiconductor substrate or a multi-layer structure (e.g., a laminate with one or more conductive layers separated by an insulator) suitable for electrically interfacing with other integrated circuit systems or external electrical circuits.

However, it is to be understood that the second substrate 120 is not to be limited to these examples. In accordance with the invention, the second substrate 120 may include any electrical interconnection structure that facilitates electrically interconnecting the bottom package 104 with other integrated circuit systems and/or external electrical circuits. For example, the second substrate 120 may include another package (e.g., an inverted internal stacking module) capable of providing a mountable top surface with land pads that allow another package or component (i.e., the top package 102) to be stacked on top.

The second substrate 120 can be electrically connected to the first surface 108 of the first substrate 106 by the interconnection 116. Generally, the interconnection 116 can be located around one or more sides along the periphery of the second substrate 120, thereby permitting the formation of a conductive post 122.

Generally, the conductive post 122 can be centrally located over or on the second substrate 120 and inwardly located from the interconnection 116. It will be appreciated by those skilled in the art that the conductive post 122 need only be offset from the interconnection 116 by a distance that is currently only limited by unwanted electrical interference occurrences.

The conductive post 122 can be an embedded lead formed within an encapsulation material 124 and exposed on one end. The opposing end of the conductive post 122 can be electrically connected to a bond pad 126 formed on a second substrate top surface 128 of the second substrate 120. In at least one embodiment, the bond pad 126 may include a conductive trace.

The conductive post 122 can be arranged and/or configured as an array or in any other manner as required by the integrated circuit packaging system 100. Notably, the arrangement and/or configuration of the conductive post 122 can be flexibly designed to accommodate the mounting of a further electrical component (e.g., the top package 102) over the conductive post 122.

It will be appreciated by those skilled in the art that the conductive post 122 may include any design or shape. In accordance with the scope of the present embodiments, it is to be understood that the design or shape of the conductive post 122 is not essential, what is important is that the conductive post 122 permit the propagation of an electrical signal.

It will be appreciated by those skilled in the art that the cross-sectional area and/or the distance between the conductive post 122 can be smaller than those of solder balls conventionally used as interconnects between the second substrate 120 and the top package 102. Accordingly, the methods, structures, and systems of the present embodiments permit a denser/higher/increased I/O count because the conductive post 122 can be formed closer together. Thus, the present inventors have discovered a way to reliably increase the density of electrical interconnects (i.e., the conductive post 122) between the top package 102 and the bottom package 104.

In at least one embodiment, the encapsulation material 124 can be deposited such that it covers the first substrate 106, the first device 114, each of the interconnection 116, the interposer 118, the second substrate 120 and the conductive post 122, while leaving a conductive post top surface 130 exposed for electrical connection. Generally, the conductive post 122 exhibit a high flow-resistivity to the mold process of the encapsulation material 124 due to the composition of the conductive post 122.

The top package 102 can be formed over and/or on the conductive post 122. Generally, the top package 102 may include active devices, passive devices, or a combination thereof. More specifically, the top package 102 may include, by way of example and not by way of limitation, one or more integrated circuit packages that transmit, receive, modulate, and/or alter electrical signals, such as leaded and non-leaded packages, internal stacking module packages, chip scale packages, systems in a package (SIP), flip-chip packages, modular packages, application-specific-integrated-circuit (ASIC) packages, RF packages, analog packages, memory packages, stacked die packages or a combination thereof. Moreover, the top package 102 may also include one or more semiconductor chips or die.

However, it is to be understood that the top package 102 covers a wide range of semiconductor chip and integrated circuit package configurations involving various sizes, dimensions, and functional applications, and the type of chip or package configuration employed should only be limited by the design specifications of the integrated circuit package.

Moreover, it will be appreciated by those skilled in the art that the present embodiments permit the testing of the top package 102 before adhering it to the conductive post 122, thereby ensuring the use of known good die or packages in the manufacturing process. Additionally, after adhering the top package 102 to the conductive post 122, this assembly can also be tested before incorporation into additional package systems. This ensures that the final product includes known good assemblies, thereby improving the manufacturing process yield for the integrated circuit packaging system 100.

By way of example, the top package 102 can be interconnected to the conductive post 122 by the external terminal 112. Generally, the external terminal 112 may include a solder ball or a solder bump depending on the top package 102 type. It will be appreciated by those skilled in the art that either of the conductive post 122 or the external terminal 112 can be treated with an organic solderability preservative or like material before interconnecting. Moreover, it is to be understood that the pitch of the external terminal 112 between the top package 102 and the conductive post 122 can be made smaller relative to a stacked package without the conductive post 122 because the conductive post 122 affords a height reduction for each of the external terminal 112.

By way of example, if the top package 102 is a ball grid array package, the external terminal 112 could be manufactured during the assembly process for the top package 102, and if the top package 102 is a flip chip type package, the external terminal 112 could be formed during the wafer fabrication process.

It will be appreciated by those skilled in the art that the present embodiments help to reduce the footprint space/area required by the integrated circuit packaging system 100 on a printed circuit board (not shown). For example, by utilizing the conductive post 122 to electrically connect the top package 102 to the bottom package 104, wire bonds are not needed to connect the top package 102 to the first substrate 106.

Moreover, although the integrated circuit packaging system 100 is shown with the top package 102 and the bottom package 104, it is to be understood that the integrated circuit packaging system 100 may include additional packages stacked on or over the top package 102 and the bottom package 104.

Referring now to FIGS. 2-29, FIGS. 2-29 include some of the same reference numbers and nomenclature used to describe the integrated circuit packaging system 100 in FIG. 1 and the process steps of FIG. 1. It is noted that the layers, devices, packages, configurations, and process steps corresponding to such reference numbers and nomenclature generally include the same characteristics (e.g., function, purpose, process techniques, etc.) as those described in reference to FIG. 1 and, therefore, their descriptions are not reiterated in detail for FIGS. 2-29. Rather the descriptions of the layers, devices, packages, configurations, and process steps corresponding to reference numbers in FIG. 1 are incorporated for the same reference numbers included in FIGS. 2-29.

Referring now to FIG. 2, therein is shown a partial cross-sectional view of the bottom package 104 in a stage of manufacture, in accordance with an embodiment of the present invention. At this stage of manufacture, the bottom package 104, which includes the first substrate 106, the first device 114, the interconnection 116, the interposer 118, and the second substrate 120, can be aligned to a top mold chase 200 including a protrusion 202 aligned with the bond pad 126 on the second substrate top surface 128.

It will be appreciated by those skilled in the art that the cross-section of each of the protrusion 202 can be configured to be a mirror image (e.g., substantially the same size and/or shape) of each corresponding one of the bond pad 126. However, each of the protrusion 202 is not limited to the preceding example and can be configured to be larger or smaller than each corresponding one of the bond pad 126.

Referring now to FIG. 3, therein is shown the structure of FIG. 2 during deposition of the encapsulation material 124. At this stage of manufacture, the top mold chase 200 engages the bottom package 104 and a bottom mold chase (not shown). Each of the protrusion 202 are aligned with each of the bond pad 126 and mated together with sufficient force to prevent mold flash or mold bleed from occurring at their interface during the deposition of the encapsulation material 124. Per this embodiment, the encapsulation material 124 can be deposited over the first substrate 106, the first device 114, each of the interconnection 116, the interposer 118, and the second substrate 120, while leaving each of the bond pad 126 exposed. The encapsulation material 124 and molding techniques using it are well known in the art and not repeated herein.

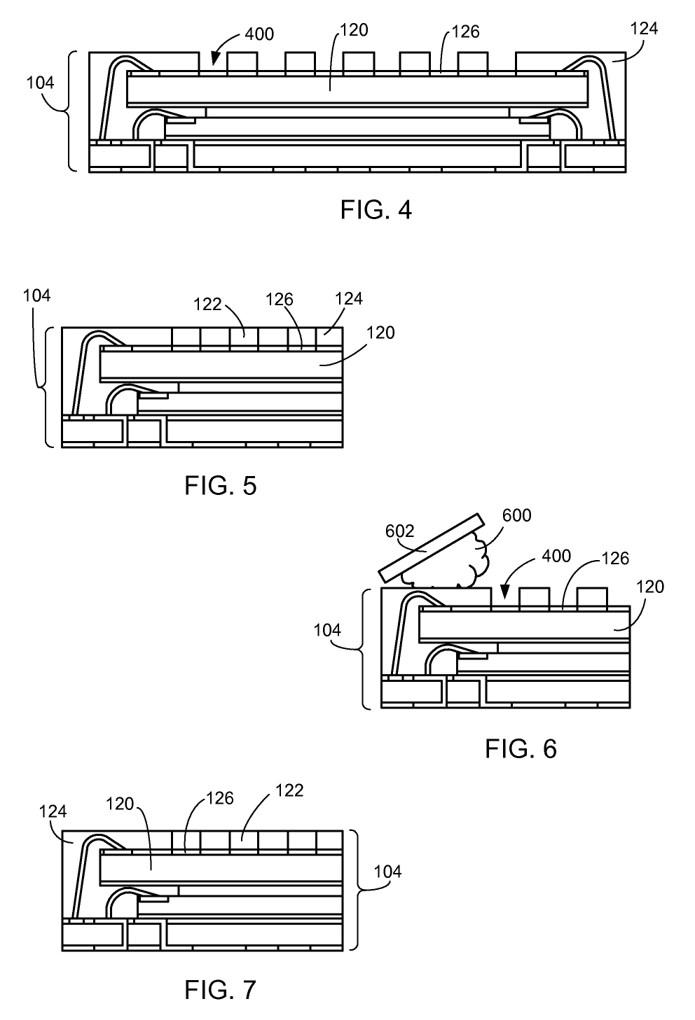

Referring now to FIG. 4, therein is shown the structure of FIG. 3 after depositing the encapsulation material 124. At this stage of manufacture, the top mold chase 200, of FIG. 3, has been removed after a sufficient curing time has elapsed for the encapsulation material 124. Upon removal, each of the protrusion 202, of FIG. 3, of the top mold chase 200 has formed an opening 400 within the encapsulation material 124. Each of the opening 400 can be formed over and aligned with respect to one of the bond pad 126, thereby providing an electrical access point to the second substrate 120 of the bottom package 104. It will be appreciated by those skilled in the art that by employing the top mold chase 200 during deposition of the encapsulation material 124 that incidences of mold flash or mold bleed can be greatly reduced as well.

Referring now to FIG. 5, therein is shown a partial cross-sectional view of the structure of FIG. 4 after forming the conductive post 122, in accordance with an embodiment of the present invention. In at least one embodiment, the opening 400, of FIG. 4, can be filled with a conductive type material, such as a metal, by electrolytic or electroless plating. Generally, the plating step can be terminated when the level of the conductive post 122 reaches the level of the encapsulation material 124. However, it is to be understood that the level of the conductive post 122 can be formed above or below the level of the encapsulation material 124 as required by the design requirements of the system. When the plating has been completed, the conductive post 122 forms an electrical contact with the bond pad 126 of the second substrate 120.

It will be appreciated by those skilled in the art that the plating step or process can be performed in one or more plating steps utilizing one or more conductive type materials.

In other embodiments, the conductive post 122 can be formed by chemical vapor deposition (CVD) or physical vapor deposition (PVD) processes. For example, the conductive post 122 could be formed by a CVD process utilizing a titanium/titanium nitride barrier layer with a tungsten fill. In such cases, the tungsten nucleation deposition sequence can employ a hydrogen-based plasma treatment to reduce or eliminate fluorine concentration at the tungsten/titanium nitride interface, thereby reducing contact resistance. As before, upon completion of the CVD or PVD process, the conductive post 122 forms an electrical contact with the bond pad 126 of the second substrate 120.

It will be appreciated by those skilled in the art that after formation of the conductive post 122 that the bottom package 104 is now ready for incorporation within the integrated circuit packaging system 100, of FIG. 1.

Referring now to FIG. 6, therein is shown a partial cross-sectional view of the structure of FIG. 4 after forming the conductive post 122, of FIG. 1, in accordance with another embodiment of the present invention. In at least one embodiment, the opening 400 can be filled with a conductive material 600, such as a metal, by squeezing the conductive material 600 into each of the opening 400. Generally, the process employs an implement 602 to apply a force to the conductive material 600, thereby exerting enough pressure upon the conductive material 600 to form the conductive post 122 in electrical contact with the bond pad 126 of the second substrate 120.

As an exemplary illustration, the conductive material 600 may include a kind of gel-type B-stage conductive material that can be cured by heating after a printing process. In at least one embodiment, a stencil mask can be placed on the top surface of the circuit to block the B-stage conductive material from flowing over onto adjacent solder resist surfaces before squeezing the conductive material 600. The conductive material 600 can be squeezed on the stencil mask, thereby filling the opening 400 and constructing the conductive post 122, after which the stencil mask can be removed.

It will be appreciated by those skilled in the art that after formation of the conductive post 122 that the bottom package 104 is now ready for incorporation within the integrated circuit packaging system 100, of FIG. 1.

Referring now to FIG. 7, therein is shown a partial cross-sectional view of the structure of FIG. 4 after forming the conductive post 122, in accordance with another embodiment of the present invention. In at least one embodiment, the opening 400, of FIG. 4, can be filled by fixing or dropping in an electrically conductive pin, such as a metal pin, to form the conductive post 122. It is to be understood that adhesives, solder, thermal treatments, and other similar methods can be used to secure the electrical connection between the electrically conductive pin (i.e., the conductive post 122) and the bond pad 126 of the second substrate 120. Additionally, it is to be understood that adhesives, solder, thermal treatments, and other similar methods can be used to prevent void formations between the electrically conductive pin (i.e., the conductive post 122) and the bond pad 126 or the encapsulation material 124.

It will be appreciated by those skilled in the art that after formation of the conductive post 122 that the bottom package 104 is now ready for incorporation within the integrated circuit packaging system 100, of FIG. 1.

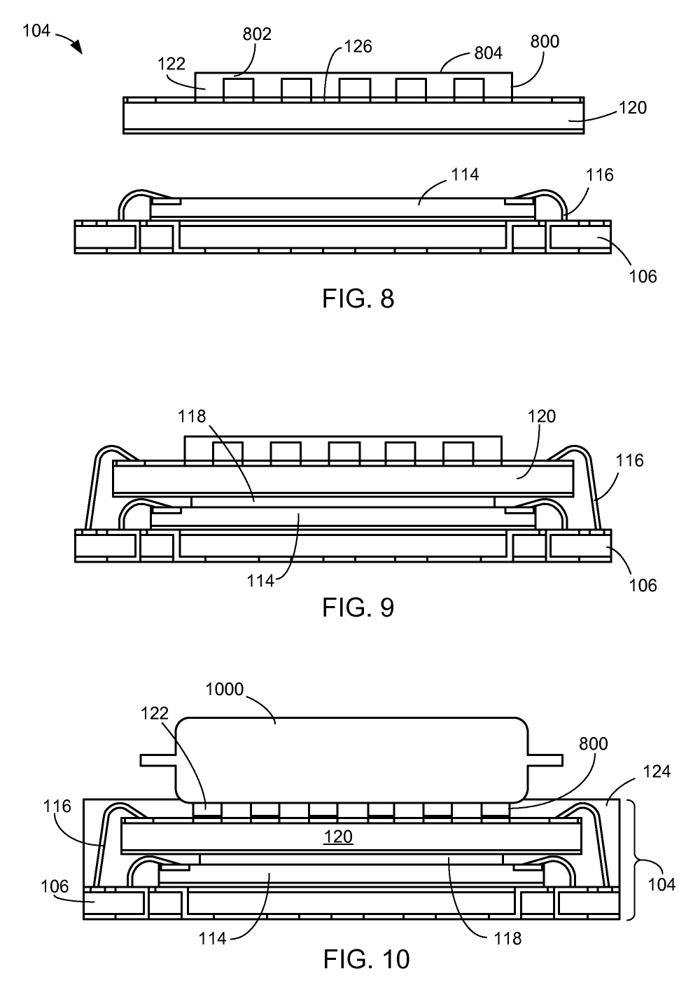

Referring now to FIG. 8, therein is shown a partial cross-sectional view of the bottom package 104 in an initial stage of manufacture, in accordance with another embodiment of the present invention. At this stage of manufacture, the second substrate 120 may include the conductive post 122 aligned over the bond pad 126 configured as a leadframe interposer 800. The first substrate 106 may include the first device 114 electrically connected to the first substrate 106 by the interconnection 116. The second substrate 120 can be aligned over the first substrate 106 at this stage of manufacture.

It will be appreciated by those skilled in the art that the leadframe interposer 800 permits formation of each of the conductive post 122 in a single/unitary process step, thereby eliminating costly and time consuming “post” formation process steps. Moreover, it will be appreciated that the leadframe interposer 800 could be aligned over one or more of the second substrate 120 in a wafer level process. Generally, the leadframe interposer 800 can help to prevent warpage, enhance coplanarity of the bottom package 104, and reduce the incidences of solder void and non-wetting that can occur between the bond pad 126, the conductive post 122 and the external terminal 112 of the top package 102, both of FIG. 1.

The leadframe interposer 800 can be made from a conductive material, such as metal, or it can be made from a conductive type material and a non-conductive material, such as a dielectric. For example, the latter embodiment may include the conductive post 122 made from a conductive type material and a spacer bar 802 made from a non-conductive material. It will be appreciated by those skilled in the art that the spacer bar 802 may include one or more bars or a continuous sheet of material interconnecting adjacent ones of the conductive post 122. Generally, the spacer bar 802 can be formed along a leadframe interposer top surface 804.

In at least one embodiment, the leadframe interposer 800 can be configured to provide an additional degree of supplementary support to the second substrate 120 and/or the bottom package 104, of FIG. 1, thereby helping to reduce incidences of substrate and/or package warpage. In such cases, the spacer bar 802 can be configured from a rigid like material that helps to prevent warpage of the leadframe interposer 800 and the second substrate 120, for example.

Referring now to FIG. 9, therein is shown the structure of FIG. 8 after joining the second substrate 120 to the first device 114. In at least one embodiment, the interposer 118 can be formed between the second substrate 120 and the first device 114. Subsequent to attaching the second substrate 120 to the first device 114, the interconnection 116 can be formed to electrically interconnect the second substrate 120 to the first substrate 106.

Referring now to FIG. 10, therein is shown the structure of FIG. 9 after forming the encapsulation material 124. In at least one embodiment, the encapsulation material 124 can be deposited over the first substrate 106, the first device 114, each of the interconnection 116, the interposer 118, the second substrate 120, and the leadframe interposer 800 including the conductive post 122 and the spacer bar 802, of FIG. 8. Subsequent to a sufficient cure time for the encapsulation material 124, an implement 1000, such as a mechanical blade or grinder, can be employed to remove the encapsulation material 124 from over the leadframe interposer 800, thereby exposing the conductive post top surface 130, of FIG. 1, for further electrical component connection. Generally, the implement 1000 removes the encapsulation material 124 by supplying an adequate force to scrape away the encapsulation material 124 formed over the conductive post 122.

It will be appreciated by those skilled in the art that any residue of the encapsulation material 124 left over the conductive post 122 after using the implement 1000 can be removed by plasma cleaning or similar methods, thereby improving subsequent electrical interconnections.

In another embodiment, the encapsulation material 124 can be deposited over the first substrate 106, the first device 114, each of the interconnection 116, the interposer 118, the second substrate 120, and the leadframe interposer 800, while leaving the leadframe interposer top surface 804, of FIG. 8, exposed. Subsequent to a sufficient cure time for the encapsulation material 124, the implement 1000 may also be employed to remove any excess of the encapsulation material 124, such as mold flash, from over the leadframe interposer 800, thereby further exposing the conductive post top surface 130 for subsequent electrical component connection.

The encapsulation material 124 and molding techniques using it are well known in the art and not repeated herein.

It will be appreciated by those skilled in the art that after removal of the encapsulation material 124 formed over the conductive post 122 by the implement 1000 that the bottom package 104 is now ready for incorporation within the integrated circuit packaging system 100, of FIG. 1.

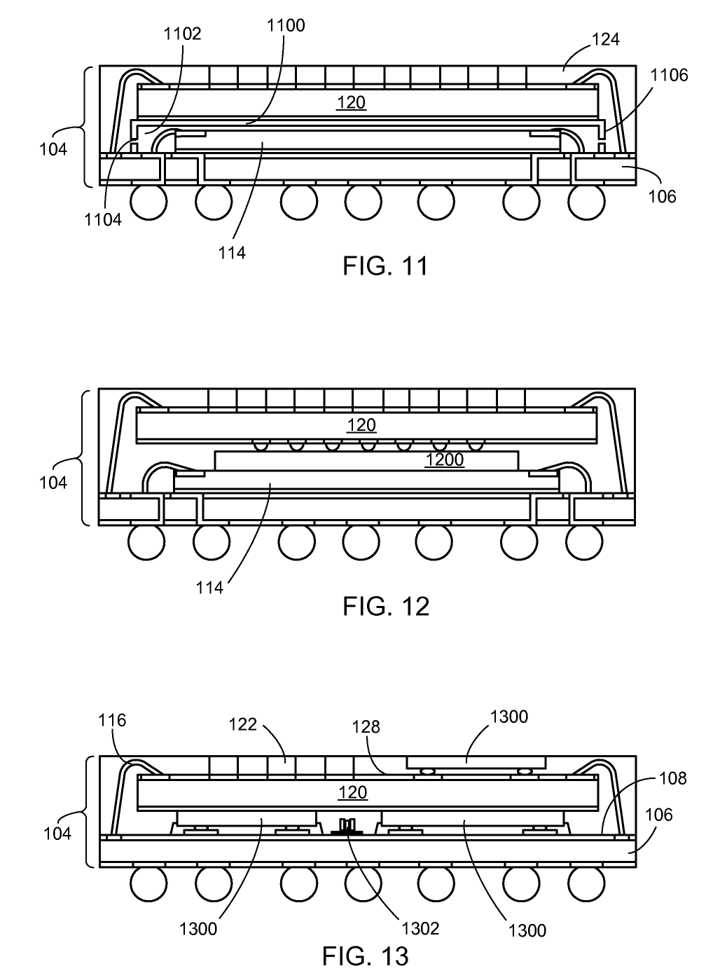

Referring now to FIG. 11, therein is shown a partial cross-sectional view of the bottom package 104, in accordance with another embodiment of the present invention. The bottom package 104 of the present embodiment is similar to the bottom package 104, of FIG. 1. However, the present embodiment differs from the embodiment of FIG. 1 by replacing the interposer 118, of FIG. 1, with a shield 1100, such as an electromagnetic interference shield or a radio frequency interference shield.

Generally, the shield 1100 encloses a void space 1102, which may include the first device 114. The shield 1100 may either contain or exclude electromagnetic energy from a volume or space, such as the void space 1102. The shield 1100 can be affixed to the first substrate 106 by solder or low impedance electrically conductive adhesive, such as a metal filled epoxy. The shield 1100 may also be electrically connected to a ground source to dissipate any absorbed electromagnetic energy.

The shield 1100 can be made from a continuous metallic material, such as copper, copper alloys, aluminum, or steel; or from a continuous plastic material coated by a surface metallization, such as copper, copper alloys, aluminum, or steel. However, it is to be understood that the composition of the shield 1100 is not to be limited to the before-mentioned materials. In accordance with the scope of the present invention, the composition of the shield 1100 may include any material that absorbs and/or dissipates electromagnetic energy.

In at least one embodiment, the shield 1100 can be designed to include an aperture 1104 formed within a sidewall 1106 by punching, for example. Generally, each of the sidewall 1106 can be processed to include one or more of the aperture 1104. However, it will be appreciated by those skilled in the art that the number of the aperture 1104 formed is only to be limited by the structural integrity requirements for the shield 1100, the ability of the shield 1100 to block or absorb disruptive electromagnetic energy, and/or the required ease desired for dispensing the encapsulation material 124 over the first device 114. It is to be understood that the aperture 1104 facilitates the dispersion of the encapsulation material 124.

Generally, the aperture 1104 can be formed anywhere along the sidewall 1106 of the shield 1100. The only limiting factor determining location of the aperture 1104 along the sidewall 1106 is the ability of the shield 1100 to block and/or absorb disruptive electromagnetic energy.

Typically, the shield 1100 and the aperture 1104 are configured in a manner that best blocks or absorbs disruptive electromagnetic energy and facilitates the dispersion of the encapsulation material 124 over the first device 114, which is located within the void space 1102 of the shield 1100.

It will be appreciated by those skilled in the art that the shield 1100 can be designed to support the second substrate 120 and/or the formation of the top package 102, of FIG. 1, over the first device 114. In at least one embodiment, the second substrate 120 can be formed on or over the shield 1100.

Referring now to FIG. 12, therein is shown a partial cross-sectional view of the bottom package 104, in accordance with another embodiment of the present invention. The bottom package 104 of the present embodiment is similar to the bottom package 104, of FIG. 1. However, the present embodiment differs from the embodiment of FIG. 1 by replacing the interposer 118, of FIG. 1, with a second device 1200.

Generally, the second device 1200 may be electrically connected to the second substrate 120 by surface mount technology commonly known within the art. The second device 1200 can also be attached to or on the first device 114 by adhesives well known within the art and not described herein. In at least one embodiment, the second device 1200 is attached to the first device 114 utilizing zero fillet technology.

Generally, the second device 1200 may include one or more active devices, passive devices, or a combination thereof, vertically stacked or located within the same plane. By way of example, and not by way of limitation, the second device 1200 may include one or more semiconductor chips or die that transmit, receive, modulate, and/or alter electrical signals, such as stacked devices, modular devices, ASIC devices, memory devices, RF devices, analog devices or a combination thereof. Furthermore, the second device 1200 may further include, by way of example and not by way of limitation, one or more integrated circuit packages that transmit, receive, modulate and/or alter electrical signals, such as leaded and non-leaded packages, internal stacking module packages, flip-chip packages, modular packages, application-specific-integrated-circuit (ASIC) packages, RF packages, analog packages, memory packages, stacked die packages or a combination thereof.

However, it is to be understood that the second device 1200 covers a wide range of semiconductor chip and integrated circuit package configurations involving various sizes, dimensions, and functional applications, and the type of chip or package configuration employed should only be limited by the design specifications of the integrated circuit package.

Moreover, it will be appreciated by those skilled in the art that the present embodiments permit the testing of the second device 1200 before adhering it to the second substrate 120, thereby ensuring the use of known good die or packages in the manufacturing process. This ensures that the final product includes known good assemblies, thereby improving the manufacturing process yield for the integrated circuit packaging system 100.

Referring now to FIG. 13, therein is shown a partial cross-sectional view of the bottom package 104, in accordance with another embodiment of the present invention. The bottom package 104 of the present embodiment is similar to the bottom package 104, of FIG. 1. However, the present embodiment differs from the embodiment of FIG. 1 by replacing the first device 114, of FIG. 1, with one or more of a system-in-package device 1300 and/or a passive device 1302.

In at least one embodiment, one or more of the system-in-package device 1300 can be electrically attached to the first surface 108 of the first substrate 106 and/or the second substrate top surface 128 by surface mount technology commonly known in the art and not repeated herein. It will be appreciated by those skilled in the art that the system-in-package device 1300 not only enhances the functional integration of the integrated circuit packaging system 100, of FIG. 1, but it may also provide mechanical support for the second substrate 120 when electrically attached to the first substrate 106.

Moreover, it will be appreciated by those skilled in the art that by utilizing one or more of the system-in-package device 1300 that various three dimensional integration schemes and alternative design structures for package-in-package designs can be obtained, while maintaining a low profile for the integrated circuit packaging system 100. For example, the vertical stacking height of the integrated circuit packaging system 100 can be reduced by employing the system-in-package device 1300 because the system-in-package device 1300 does not employ wire bond interconnects, which typically require offset of the second substrate 120 to accommodate wire bond loop height.

In at least one embodiment, one or more of the system-in-package device 1300 can be formed over the second substrate top surface 128 inward from the interconnection 116. In such cases, the conductive post 122 can still be located over or on at least a portion of the second substrate top surface 128 inward from the interconnection 116.

Generally, the passive device 1302 may include, but is not limited to, resistors, capacitors, inductors, or combinations thereof. In at least one embodiment, the passive device 1302 can be attached to the first substrate 106 by surface mount technology commonly known in the art and not repeated herein.

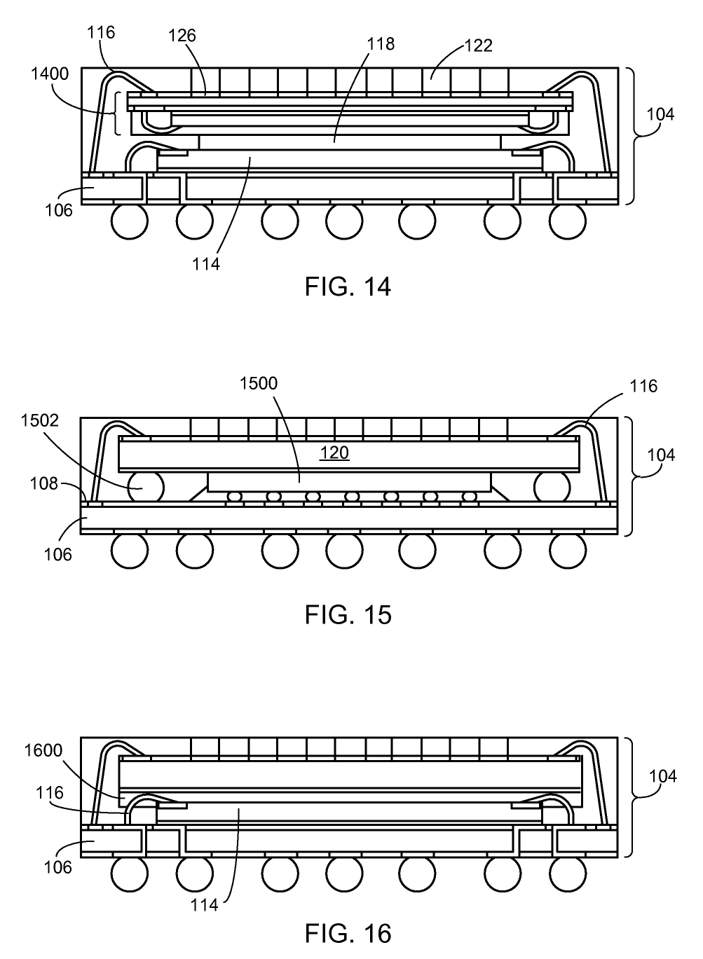

Referring now to FIG. 14, therein is shown a partial cross-sectional view of the bottom package 104, in accordance with another embodiment of the present invention. The bottom package 104 of the present embodiment is similar to the bottom package 104, of FIG. 1. However, the present embodiment differs from the embodiment of FIG. 1 by replacing the second substrate 120, of FIG. 1, with an internal stacking module 1400.

In at least one embodiment, the internal stacking module 1400 can be located over and attached to the first device 114 by the interposer 118. In such cases, the internal stacking module 1400 can be inverted and electrically connected to the first substrate 106 by the interconnection 116. As per the embodiment of FIG. 1, the conductive post 122 can be electrically connected to the bond pad 126 of the internal stacking module 1400.

Referring now to FIG. 15, therein is shown a partial cross-sectional view of the bottom package 104, in accordance with another embodiment of the present invention. The bottom package 104 of the present embodiment is similar to the bottom package 104, of FIG. 1. However, the present embodiment differs from the embodiment of FIG. 1 by replacing the first device 114, of FIG. 1, with one or more of a flip-chip device 1500 and one or more of a support structure 1502.

In at least one embodiment, one or more of the flip-chip device 1500 can be electrically attached to the first surface 108 of the first substrate 106 by surface mount technology commonly known in the art and not repeated herein. It will be appreciated by those skilled in the art that the flip-chip device 1500 not only enhances the functional integration of the integrated circuit packaging system 100, of FIG. 1, but it may also provide mechanical support for the second substrate 120, if necessary.

Moreover, it will be appreciated by those skilled in the art that by utilizing one or more of the flip-chip device 1500 that various three dimensional integration schemes and alternative design structures for package-in-package designs can be obtained, while maintaining a low profile for the integrated circuit packaging system 100. For example, the vertical stacking height of the integrated circuit packaging system 100 can be reduced by employing the flip-chip device 1500 because the flip-chip device 1500 does not employ wire bond interconnects, which typically require offset of the second substrate 120 to accommodate wire bond loop height.

The bottom package 104 may also include one or more of the support structure 1502 formed outside of the flip-chip device 1500 and along the periphery of the second substrate 120. The support structure 1502 can provide additional support for the second substrate 120 or totally support the second substrate 120 (i.e., the second substrate 120 does not contact the flip-chip device 1500). In at least one embodiment, the support structure 1502 can be made from a conductive material that provides a supplementary electrical interconnect (i.e., in addition to the interconnection 116) between the first substrate 106 and the second substrate 120. In another embodiment, the support structure 1502 can be made from a non-conductive material.

Referring now to FIG. 16, therein is shown a partial cross-sectional view of the bottom package 104, in accordance with another embodiment of the present invention. The bottom package 104 of the present embodiment is similar to the bottom package 104, of FIG. 1. However, the present embodiment differs from the embodiment of FIG. 1 by replacing the interposer 118, of FIG. 1, with a lead-in-film interposer 1600.

Per this embodiment, the interconnection 116 between the first device 114 and the first substrate 106 can be partially encapsulated by the lead-in-film interposer 1600. In at least one embodiment, the lead-in-film interposer 1600 may include a non-conductive adhesive. In other embodiments where the lead-in-film interposer 1600 includes an adhesive or encapsulant that is a B-stage type material, the structure can be referred to as a wire-in-film configuration. A B-stage type material is soft enough to have bond wires embedded in it without causing wire sweep problems and can be cured to a rigid state. It will be appreciated by those skilled in the art that the lead-in-film interposer 1600 can electrically isolate and/or mechanically support the interconnection 116.

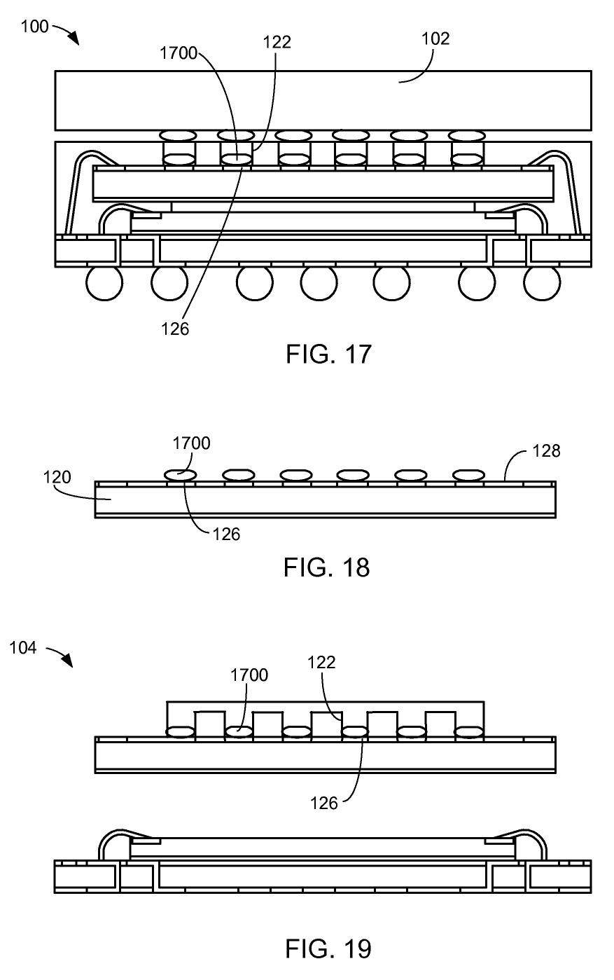

Referring now to FIG. 17, therein is shown a partial cross-sectional view of the integrated circuit packaging system 100, in accordance with another embodiment of the present invention. The integrated circuit packaging system 100 of the present embodiment is similar to the integrated circuit packaging system 100, of FIG. 1. However, the present embodiment differs from the embodiment of FIG. 1 by forming an interface 1700 between the bond pad 126 and the conductive post 122. In at least one embodiment, the interface 1700 can be referred to as solder on pad (SOP) technology. Per the embodiments herein, the interface 1700 is defined as a low resistance electrical contact formed between two conductive regions.

Generally, the interface 1700 can be formed from conductive materials including metallic and inter-metallic compounds. It will be appreciated by those skilled in the art that the interface 1700 can improve the adhesion strength between the bond pad 126 and the conductive post 122, while permitting stress release transfer from the top package 102 due to the soft characteristics of the interface 1700. Moreover, it will be appreciated by those skilled in the art that the conductive post 122 can be easily aligned over the interface 1700 during reflow because of the reflow characteristics of the interface 1700.

Notably, the interface 1700 and the conductive post 122 both provide solutions to the common high density package on package problems of requiring increased stand-off between packages and finer pitch I/O counts between packages. For example, the height of either of the interface 1700 or the conductive post 122 can be easily adjusted, thereby providing the designer with an easy way to accommodate the required stand-off height necessary between packages. Additionally, the combination of the interface 1700 and the conductive post 122 permit a higher density of I/O counts because of their ability to solve the stand-off height problem without requiring thicker interconnections.

Referring now to FIG. 18, therein is shown a partial cross-sectional view of the second substrate 120 in an initial stage of manufacture, in accordance with another embodiment of the present invention. At this stage of manufacture, the interface 1700 can be formed over or on the bond pad 126 located on the second substrate top surface 128.

Referring now to FIG. 19, therein is shown a partial cross-sectional view of the bottom package 104 including the interface 1700 during a stage of manufacture, in accordance with another embodiment of the present invention. The bottom package 104 of the present embodiment and the methods forming it are similar to the bottom package 104, of FIG. 8. However, the present embodiment differs from the embodiment of FIG. 8 by forming the interface 1700 between the bond pad 126 and the conductive post 122.

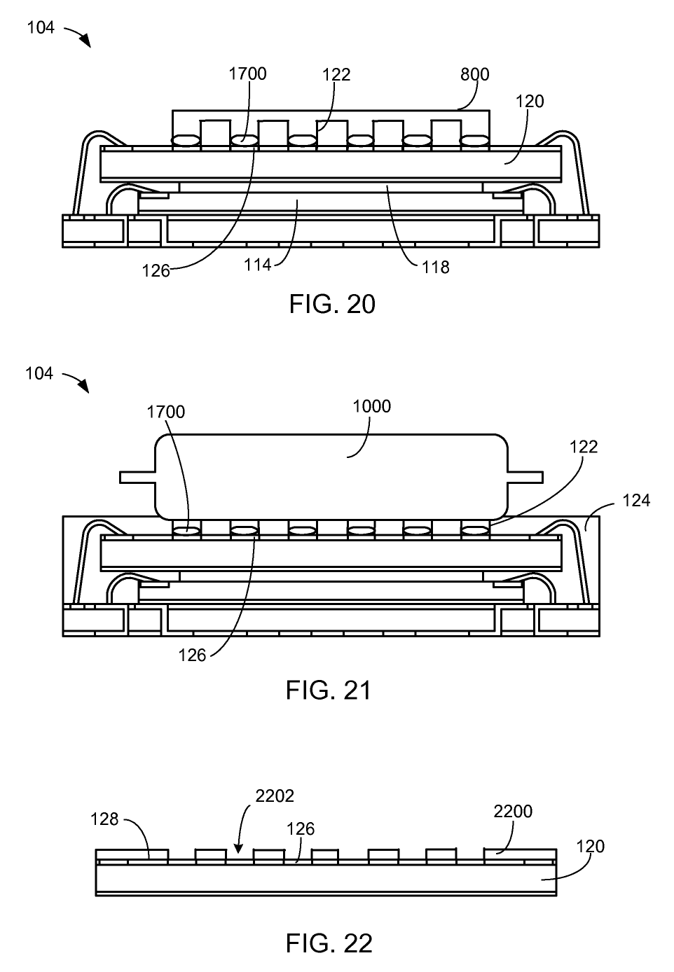

Referring now to FIG. 20, therein is shown the structure of FIG. 19 after joining the second substrate 120 to the first device 114 via the interposer 118. The bottom package 104 of the present embodiment and the methods forming it are similar to the bottom package 104, of FIG. 9. However, the present embodiment differs from the embodiment of FIG. 9 by forming the interface 1700 between the bond pad 126 and the conductive post 122. Per this embodiment, the conductive post 122 of the leadframe interposer 800 can be electrically connected to the bond pad 126 through the interconnect 1700.

Referring now to FIG. 21, therein is shown the structure of FIG. 20 after forming the encapsulation material 124. The bottom package 104 of the present embodiment and the methods forming it are similar to the bottom package 104, of FIG. 10. However, the present embodiment differs from the embodiment of FIG. 10 by forming the interface 1700 between the bond pad 126 and the conductive post 122.

It will be appreciated by those skilled in the art that after removal of the encapsulation material 124 formed over the conductive post 122 by the implement 1000 that the bottom package 104 is now ready for incorporation within the integrated circuit packaging system 100, of FIG. 17.

Referring now to FIG. 22, therein is shown a partial cross-sectional view of the second substrate 120 in an initial stage of manufacture, in accordance with another embodiment of the present invention. At this stage of manufacture, the second substrate 120 includes a first passivation layer 2200 formed over or on the second substrate top surface 128 including an opening 2202 exposing the bond pad 126. By way of example, the first passivation layer 2200 may include a dielectric material.

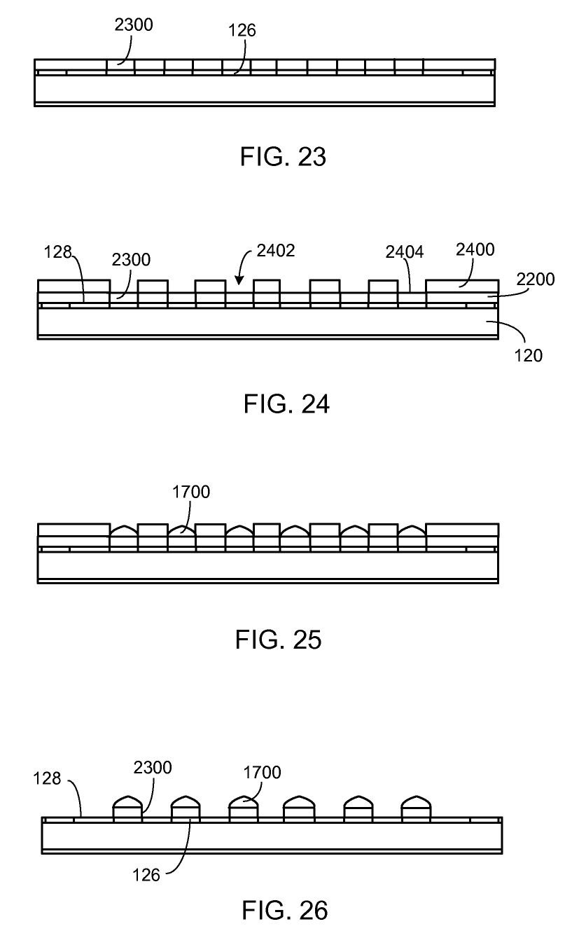

Referring now to FIG. 23, therein is shown the structure of FIG. 22 after formation of a first conductive post 2300. The first conductive post 2300 can be formed on or over the bond pad 126 within the opening 2202, of FIG. 22. It will be appreciated by those skilled in the art that the first conductive post 2300 can be formed by the plating method of FIG. 5, by the squeezing method of FIG. 6, and/or by the fix/drop in method of FIG. 7, for example. However, the formation of the first conductive post 2300 is not limited to the preceding examples and can be manufactured by any method that permits formation of a low resistance electrical interconnection within the opening 2202.

Referring now to FIG. 24, therein is shown the structure of FIG. 23 after formation of a second passivation layer 2400. At this stage of manufacture, the second substrate 120 now includes the first passivation layer 2200 formed over or on the second substrate top surface 128, a first conductive post 2300 formed within the first passivation layer 2200, and a second passivation layer 2400 formed over or on the first passivation layer 2200. The second passivation layer 2400 has been processed to include an opening 2402 exposing a first conductive post top surface 2404. By way of example, the second passivation layer 2400 may include a dielectric material.

Referring now to FIG. 25, therein is shown the structure of FIG. 24 after formation of the interface 1700. The interface 1700 can be formed on or over the first conductive post top surface 2404, of FIG. 24, within the opening 2402, of FIG. 24. It will be appreciated by those skilled in the art that the amount of the interface 1700 deposited can vary with the desired stand-off height. As with FIG. 17, the interface 1700 can improve adhesion strength, stress transfer, and alignment.

Referring now to FIG. 26, therein is shown the structure of FIG. 25 after further processing. At this stage of manufacture, the first passivation layer 2200 and the second passivation layer 2400, both of FIG. 25, can be removed by processes well known within the art and not repeated herein. Subsequent to the removal of the first passivation layer 2200 and the second passivation layer 2400, the second substrate top surface 128 now includes the first conductive post 2300 formed on or over the bond pad 126 and the interface 1700 formed on or over the first conductive post 2300.

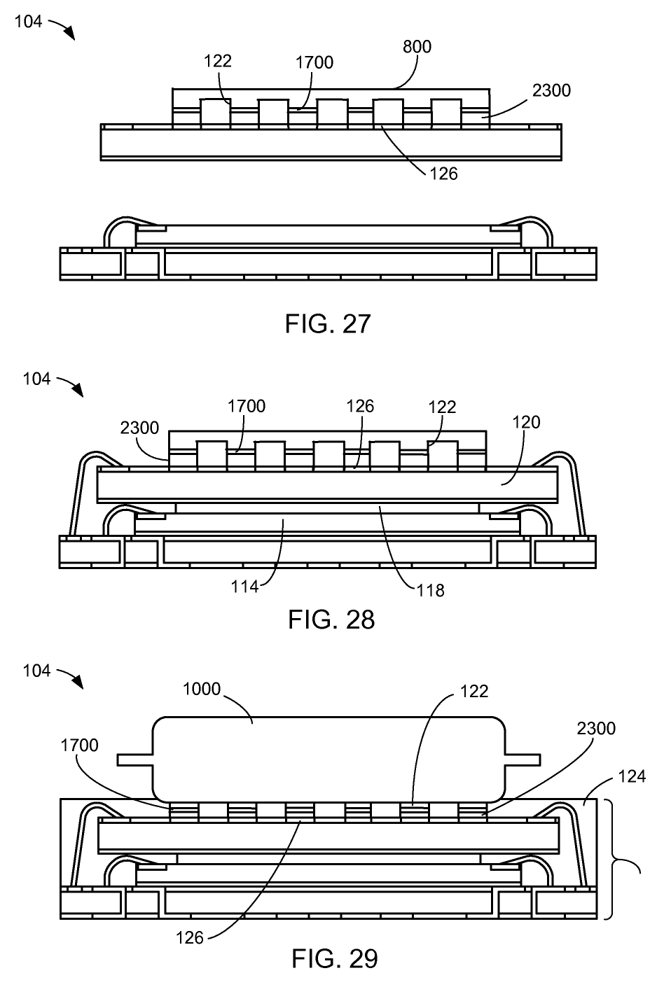

Referring now to FIG. 27, therein is shown a partial cross-sectional view of the bottom package 104 including the first conductive post 2300 and the interface 1700 during a stage of manufacture, in accordance with another embodiment of the present invention. The bottom package 104 of the present embodiment and the methods forming it are similar to the bottom package 104, of FIG. 8. However, the present embodiment differs from the embodiment of FIG. 8 by forming the first conductive post 2300 on or over the bond pad 126 and the interface 1700 on or over the first conductive post 2300. Per this embodiment, the conductive post 122 of the leadframe interposer 800 can be electrically connected to the bond pad 126 through the first conductive post 2300 and the interconnect 1700.

Referring now to FIG. 28, therein is shown the structure of FIG. 27 after joining the second substrate 120 to the first device 114 via the interposer 118. The bottom package 104 of the present embodiment and the methods forming it are similar to the bottom package 104, of FIG. 9. However, the present embodiment differs from the embodiment of FIG. 9 by forming the first conductive post 2300 and the interface 1700 between the bond pad 126 and the conductive post 122.

Referring now to FIG. 29, therein is shown the structure of FIG. 28 after forming the encapsulation material 124. The bottom package 104 of the present embodiment and the methods forming it are similar to the bottom package 104, of FIG. 10. However, the present embodiment differs from the embodiment of FIG. 10 by forming the first conductive post 2300 and the interface 1700 between the bond pad 126 and the conductive post 122.

It will be appreciated by those skilled in the art that after removal of the encapsulation material 124 formed over the conductive post 122 by the implement 1000 that the bottom package 104 is now ready for incorporation within the integrated circuit packaging system 100, of FIG. 17.

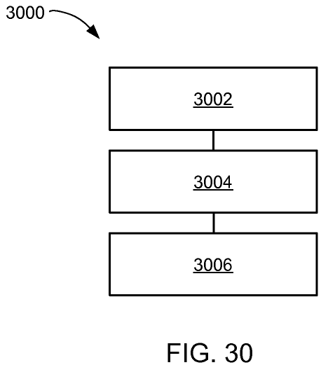

Referring now to FIG. 30, therein is shown a flow chart of a method 3000 of manufacture of an integrated circuit packaging system 100 in an embodiment of the present invention. The method 3000 includes: providing a bottom package including a first device over a first substrate and a second substrate over the first device in a block 3002 forming an encapsulation material over the bottom package with an opening over the second substrate in a block 3004; and forming a conductive post within the opening in a block 3006.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization.

It has been discovered that the present invention thus has numerous aspects. One such aspect is that the present invention can increase the density of I/O leads between a top package and a bottom package by utilizing conductive posts instead of solder balls.

Another aspect is that the present invention can eliminate the occurrence of solder ball shorting by employing conductive posts.

Another aspect is that the present invention prevents the occurrence of mold flash problems common to solder ball interconnects (e.g., due to tape assistant mold method) between a top package and a bottom package by utilizing conductive posts.

Another aspect is that the present invention permits stand-off height adjustment and finer pitch I/O counts by using an interface and a first conductive post.

Another aspect is that the present invention improves adhesion strength, stress transfer, and alignment between a conductive post and a bond pad or between one or more conductive posts by employing an interface.

Yet another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing a bottom package including a first device over a first substrate and a second substrate over the first device;
forming an encapsulation material over the bottom package with an opening over the second substrate; and
forming a conductive post within the opening.

2. The method as claimed in claim 1 wherein:
forming the conductive post within the opening includes plating.

3. The method as claimed in claim 1 wherein:
forming the conductive post within the opening includes squeezing a conductive material into the opening.

4. The method as claimed in claim 1 wherein:
forming the conductive post within the opening includes fixing or dropping in the conductive post.

5. The method as claimed in claim 1 wherein:
forming the encapsulation material over the bottom package includes utilizing a top mold chase with a protrusion aligned over a bond pad.

6. The method as claimed in claim 1 further comprising:
forming an interface between a bond pad and the conductive post.

7. A method of manufacture of an integrated circuit packaging system comprising:
providing a bottom package including a leadframe interposer with a conductive post;
forming an encapsulation material over the bottom package; and
removing the encapsulation material from over the leadframe interposer to expose the conductive post.

8. The method as claimed in claim 7 wherein:
removing the encapsulation material from over the leadframe interposer to expose the conductive post includes employing an implement to scrape away the encapsulation material.

9. The method as claimed in claim 7 wherein:
providing the leadframe interposer includes forming the conductive post over each of a bond pad in a single step.

10. The method as claimed in claim 7 wherein:
providing the leadframe interposer includes providing the leadframe interposer made from a conductive material and a non-conductive material.

11. The method as claimed in claim 7 wherein:
providing the leadframe interposer includes providing the leadframe interposer with each of the conductive post interconnected by a spacer bar.

12. The method as claimed in claim 7 further comprising:
forming an interface between a bond pad and the conductive post.

13. An integrated circuit packaging system comprising:
a bottom package including a first device over a first substrate and a second substrate over the first device;
a leadframe interposer with a conductive post over the second substrate; and
an encapsulation material.

14. The system as claimed in claim 13 wherein:
the leadframe interposer is made from a conductive material and a non-conductive material.

15. The system as claimed in claim 13 wherein:
the leadframe interposer includes each of the conductive post interconnected by a spacer bar.

16. The system as claimed in claim 13 wherein:
the leadframe interposer electrically interconnects a top package to a carrier substrate.

17. The system as claimed in claim 13 wherein:
the first device and the second substrate are electrically connected to the first substrate.

18. The system as claimed in claim 13 wherein:
the second substrate is electrically connected to a top package by the conductive post and electrically connected to the first substrate by an interconnection.

19. The system as claimed in claim 13 wherein:
the bottom package includes a shield.

20. The system as claimed in claim 13 wherein:
the bottom package includes a system-in-package device.

21. The system as claimed in claim 13 wherein:
the bottom package includes an internal stacking module.

22. The system as claimed in claim 13 wherein:
the bottom package includes lead-in-film technology.

23. The system as claimed in claim 13 further comprising:
an interface between a bond pad and the conductive post.
